(19) United States
(12) Patent Application Publication
(10) Pub. No.: US 2023/0275114 A1
(43) Pub. Date: Aug. 31, 2023

(54) DISPLAY DEVICE AND TILED DISPLAY DEVICE INCLUDING THE SAME

(71) Applicant: Samsung Display Co., LTD., Yongin-si (KR)

(72) Inventors: Dae Hwan JANG, Seoul (KR); Seok Hyun NAM, Seoul (KR); Jin Ho Cho, Cheonan-si (KR)

(73) Assignee: Samsung Display Co., LTD., Yongin-si (KR)

(21) Appl. No.: 17/968,371

(22) Filed: Oct. 18, 2022

(30) Foreign Application Priority Data
Feb. 28, 2022 (KR) 10-2022-0025990

(51) Int. Cl. H01L 27/15

(52) U.S. Cl. CPC H01L 27/156

(57) ABSTRACT

A display device includes a first barrier insulating layer including a first contact hole, a first metal layer disposed on the first barrier insulating layer, the first metal layer including a protruding part inserted in the first contact hole to protrude from below the first barrier insulating layer, and a recessed part formed in the first contact hole, a substrate disposed on the first metal layer and including a second contact hole, a second metal layer disposed on the substrate and inserted in the second contact hole to be connected to the first metal layer, a thin-film transistor including an active layer and a third metal layer overlapping the active layer, and a flexible film disposed below the first barrier insulating layer and including a lead electrode electrically connected to the protruding part of the first metal layer.

### CROSS-REFERENCE TO RELATED APPLICATION(S)

This application claims priority to and benefits of Korean Patent Application No. 10-2022-0025990 under 35 U.S.C. § 119, filed on Feb. 28, 2022, in the Korean Intellectual Property Office, the entire contents of which are incorporated herein by reference.

### BACKGROUND

### 1. Technical Field

Embodiments relate to a display device and a tiled display device including the display device.

### 2. Description of the Related Art

As the information society has developed, the demand for display devices for displaying images has diversified. For example, display devices have been applied to various electronic devices such as smart phones, digital cameras, notebook computers, navigation systems, and smart televisions. Examples of display devices include flat panel display devices such as a liquid crystal display (LCD) device, a field emission display (FED) device, or an organic light-emitting diode (OLED) display device. A light-emitting display device, which is a type of flat panel display device, includes light-emitting elements capable of emitting light and may thus display an image without a requirement of a backlight unit for providing light to a display panel.

In case that a large-size display device is fabricated, the defect rate of light-emitting elements may increase due to an increase in the number of pixels, and the productivity or reliability of the display device may decrease. To solve these problems, a tiled display device with a large screen may be implemented by connecting multiple display devices having a relatively small size. The tiled display device may include seams (or boundary portions) between the multiple display devices due to the non-display areas or bezels of the multiple display devices. However, in case that an image is being displayed on the entire screen of the tiled display device, the seams cause the perception of discontinuity, adversely affecting the perception of immersion of the image.

### SUMMARY

Embodiments provide a tiled display device including a display device capable of lowering the temperature and pressure for bonding flexible films.

Embodiments also provide a tiled display device capable of eliminating the perception of discontinuity between multiple display devices and enhancing the perception of immersion of an image by preventing boundary portions or non-display areas between the multiple display devices from being recognized or visible.

However, embodiments of the disclosure are not limited to those set forth herein. The above and other embodiments will become more apparent to one of ordinary skill in the art to which the disclosure pertains by referencing the detailed description of the disclosure given below.

According to an embodiment, a display device may include a first barrier insulating layer including a first contact hole, a first metal layer disposed on the first barrier insulating layer, the first metal layer including a protruding part inserted in the first contact hole to protrude from below the first barrier insulating layer, and a recessed part formed in the first contact hole, a substrate disposed on the first metal layer and including a second contact hole, a second metal layer disposed on the substrate and inserted in the second contact hole to be connected to the first metal layer, a thin-film transistor including an active layer and a third metal layer overlapping the active layer, and a flexible film disposed below the first barrier insulating layer and including a lead electrode electrically connected to the protruding part of the first metal layer.

The display device may further include an adhesive part having an insulating property and attaching the flexible film to a bottom surface of the first barrier insulating layer.

The display device may further include a filler part filling the recessed part of the first metal layer.

The filler part may include an organic material or photoresist.

The display device may further include a second barrier insulating layer disposed on the first barrier insulating layer, the first metal layer, and the filler part.

The first barrier insulating layer may include a plurality of first contact holes. The first metal layer may include a plurality of protruding parts inserted in each of the plurality of first contact holes. The lead electrode may be in direct contact with the plurality of protruding parts.

Each of the plurality of protruding parts may have short sides in a first direction and long sides in a second direction intersecting the first direction. The plurality of protruding parts may be spaced apart from each other in the first direction.

The first metal layer may include a fan-out line, the fan-out line may include a lower fan-out line disposed on the first barrier insulating layer, and an upper fan-out line disposed on the lower fan-out line. A thickness of the upper fan-out line may be greater than a thickness of the lower fan-out line.

The flexible film may provide a data voltage, a power supply voltage, or a gate signal to the thin-film transistor through the first metal layer.

The display device may further include a display driver mounted on the flexible film and providing the data voltage, the power supply voltage, or the gate signal.

The second metal layer includes a connecting lines and a voltage line, and the voltage line may be electrically connected to the thin-film transistor.

The display device may further include a fourth metal layer disposed on the third metal layer. The fourth metal layer may include a first connecting electrode. An end of the first connecting electrode may be connected to the voltage line. Another end of the first connecting electrode may be connected to the thin-film transistor.

The display device may further include a light-emitting element layer disposed on the fourth metal layer. The fourth metal layer further includes a second connecting electrode, and the light-emitting element layer may include a first electrode connected to the second connecting electrode, a second electrode spaced apart from the first electrode, and light-emitting elements aligned between the first and second electrodes and electrically connected between the first and second electrodes.

According to an embodiment, a display device may include a barrier insulating layer including a first contact hole, a first metal layer disposed on the barrier insulating layer, the first metal layer including a protruding part inserted in the first contact hole to protrude from below the barrier insulating layer, and a recessed part formed in the first contact hole, a substrate disposed on the first metal layer and including a second contact hole, a second metal layer disposed on the substrate, a thin-film transistor electrically connected to the second metal layer, a flexible film disposed below the barrier insulating layer and including a lead electrode electrically connected to the protruding part of the first metal layer, and an adhesive part not overlapping the protruding part of the first metal layer in a thickness direction.

The display device may further include a filler part filling the recessed part of the first metal layer.

The adhesive part may do not overlap the filler part in the thickness direction.

The second metal layer may include a connecting line, and the connecting line may be inserted in the second contact hole to be connected to the first metal layer.

The thin-film transistor may include an active layer including a drain electrode, a semiconductor area, and a source electrode, and a gate electrode disposed on the active layer.

The first metal layer may include a fan-out line, the second metal layer may include a voltage line, and the voltage line may be electrically connected to the thin-film transistor.

According to an embodiment, a tiled display device may include a plurality of display devices, each of the display devices having a display area including a plurality of pixels, and a non-display area surrounding the display area, and a bonding part bonding the display devices to one another. Each of the display devices may include a barrier insulating layer including a first contact hole, a first metal layer disposed on the barrier insulating layer and including a protruding part inserted in the first contact hole to protrude from below the barrier insulating layer, a substrate disposed on the first metal layer and including a second contact hole, a second metal layer disposed on the substrate, a thin-film transistor electrically connected to the second metal layer, and a flexible film disposed below the barrier insulating layer and including a lead electrode electrically connected to the protruding part of the first metal layer.

According to the aforementioned and other embodiments, the protruding parts of fan-out lines may protrude from below a barrier insulating layer, and adhesive parts may have a low viscosity and high fluidity. The adhesive parts may readily move during the bonding of flexible films. Also, as the lead electrodes of the flexible films are in direct contact with the protruding parts of the fan-out lines, the temperature and pressure for bonding the flexible films may be reduced, and the manufacturing cost of a display device may be lowered.

As display drivers below a substrate are electrically connected to connecting lines on the substrate, the size of the non-display area of a display device may be reduced or minimized. Accordingly, the distance between multiple display devices included in a tiled display device may be reduced or minimized, and as a result, the non-display area or the seam between the multiple display devices may be prevented from becoming recognizable to a user.

It should be noted that the effects of the disclosure are not limited to those described above, and other effects of the disclosure will be apparent from the following description.

### BRIEF DESCRIPTION OF THE DRAWINGS

The above and other aspects and features of the disclosure will become more apparent by describing in embodiments thereof with reference to the attached drawings, in which:

FIG. 1 is a schematic plan view of a tiled display device according to an embodiment;

FIG. 2 is a schematic cross-sectional view taken along line I-I′ of FIG. 1;

FIG. 3 is a schematic enlarged cross-sectional view of an area A1 of FIG. 2;

FIG. 4 is a schematic bottom view of a display device according to an embodiment;

FIG. 5 is a schematic enlarged bottom view of the display device of FIG. 4;

FIG. 6 is schematic enlarged bottom view of a display device according to an embodiment;

FIG. 7 is a schematic cross-sectional view of the display device of FIG. 6;

FIG. 8 is a schematic enlarged bottom view of a display device according to an embodiment;

FIG. 9 is a schematic cross-sectional view taken along line II-IF of FIG. 1; and

FIGS. 10, 11, 12, 13, 14, 15, and 16 are schematic cross-sectional views illustrating how to fabricate a display device according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive. For example, specific shapes, configurations, and characteristics of an embodiment may be used or implemented in other embodiments.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for specific materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Further, the X-axis, the Y-axis, and the Z-axis are not limited to three axes of a rectangular coordinate system, and thus the X-, Y-, and Z-axes, and may be interpreted in a broader sense. For example, the X-axis, the Y-axis, and the Z-axis may be perpendicular to one another, or may represent different directions that are not perpendicular to one another.

For the purposes of this disclosure, “at least one of A and B” may be construed as understood to mean A only, B only, or any combination of A and B. Also “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” may encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation, not as terms of degree, and thus are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the illustrated shapes of regions, but are to include deviations in shapes that result from, for instance, manufacturing. In this manner, regions illustrated in the drawings may be schematic in nature, and the shapes of these regions may not reflect actual shapes of regions of a device and are not necessarily intended to be limiting.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the disclosure. Further, the blocks, units, parts, and/or modules of some embodiments may be physically combined into more complex blocks, units, parts, and/or modules without departing from the scope of the disclosure.

Unless otherwise defined or implied herein, all terms (including technical and scientific terms) used herein have the same meaning as commonly understood by one of ordinary skill in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or overly formal sense, unless clearly so defined herein.

Hereinafter, detailed embodiments will be described with reference to the accompanying drawings.

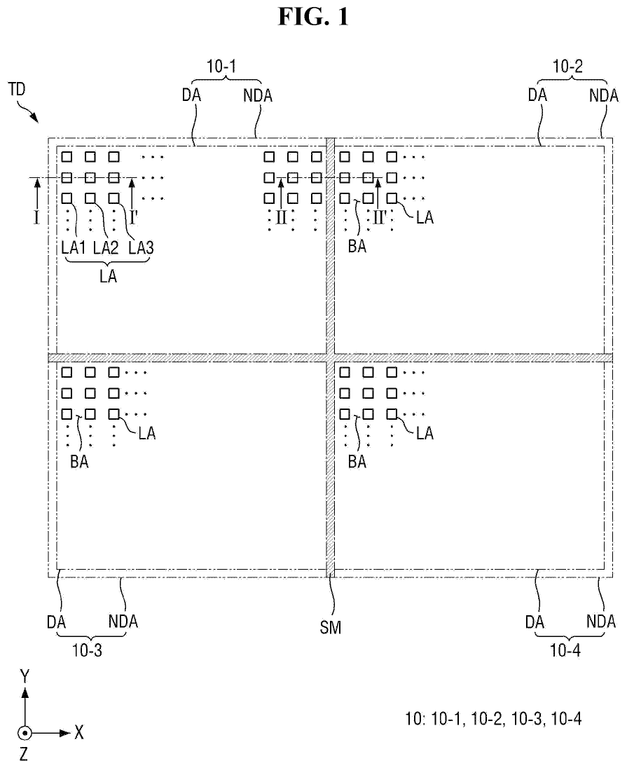

FIG. 1 is a schematic plan view of a tiled display device according to an embodiment.

Referring to FIG. 1, a tiled display device TD may include display devices 10. The display devices 10 may be arranged in a lattice pattern, but embodiments are not limited thereto. The display devices 10 may be connected in a first direction (or an X-axis direction) or a second direction (or a Y-axis direction), and the tiled display device TD may have a specific shape. For example, the display devices 10 may all have the same size, but embodiments are not limited thereto. In another example, the display devices 10 may have different sizes.

The tiled display device TD may include first, second, third, and fourth display devices 10-1, 10-2, 10-3, and 10-4. The number of display devices 10 included in the tiled display device TD and how the display devices 10 are coupled to one another are not limited thereto. The number of display devices 10 included in the tiled display device TD may be determined by the size of the display devices 10 and the size of the tiled display device TD.

The display devices 10 may have a rectangular shape with a pair of long sides and a pair of short sides. The display devices 10 may be arranged by connecting the long sides or the short sides of each of the display devices 10. Some of the display devices 10 may be arranged along the edges of the tiled display device TD to form the sides of the tiled display device TD. Some of the display devices 10 may be arranged at the corners (or the corner areas) of the tiled display device TD to form each pair of adjacent sides of the tiled display device TD. Some of the display devices 10 may be disposed in the middle of the tiled display device TD and may be surrounded by other display devices 10.

Each of the display devices 10 may include a display area DA and a non-display area NDA. The display area DA may include pixels and may display an image. Each of the pixels may include organic light-emitting diodes (OLEDs) including organic light-emitting layers, quantum-dot light-emitting diodes (QLEDs) including quantum-dot light-emitting layers, micro-light-emitting diodes (microLEDs), or inorganic light-emitting diodes (LEDs) including an inorganic semiconductor. Each of the pixels will hereinafter be described as including inorganic LEDs, but embodiments are not limited thereto. The non-display area NDA may be disposed around the display area DA to surround the display area DA and may not display an image.

Each of the display devices 10 may include pixels, which are arranged in multiple rows and multiple columns, in the display area DA. Each of the pixels may include an emission area LA, which is defined by a pixel-defining film or a bank, and may emit light having a specific peak wavelength through the emission area LA. For example, the display area DA of each of the display devices 10 may include first emission areas LA1, second emission areas LA2, and third emission areas LA3. The first emission areas LA1, the second emission areas LA2, and the third emission areas LA3 may be areas that output light generated by light-emitting elements of each of the display devices 10 to the outside of the tiled display device TD.

The first emission areas LA1, the second emission areas LA2, and the third emission areas LA3 may emit light having a specific peak wavelength to the outside of the tiled display device TD. The first emission areas LA1, the second emission areas LA2, and the third emission areas LA3 may emit first-color light, second-color light, and third-color light, respectively. For example, the first-color light may be red light having a peak wavelength of about 610 nm to about 650 nm, the second-color light may be green light having a peak wavelength of about 510 nm to about 550 nm, and the third-color light may be blue light having a peak wavelength of about 440 nm to about 480 nm. However, embodiments are not limited to this example.

The first emission areas LA1, the second emission areas LA2, and the third emission areas LA3 may be sequentially arranged in the first direction (or the X-axis direction) in each of the display areas DA. For example, the third emission areas LA3 may have a size larger than that of the first emission areas LA1, and the first emission areas LA1 may have a size larger than that of the second emission areas LA2. However, embodiments are not limited to this example. In another example, the first emission areas LA1, the second emission areas LA2, and the third emission areas LA3 may all have substantially the same size.

The display area DA of each of the display devices 10 may further include a light-blocking area BA, which surrounds the first emission areas LA1, the second emission areas LA2, and the third emission areas LA3. The light-blocking area BA may prevent beams of light emitted from the first emission areas LA1, the second emission areas LA2, and the third emission areas LA3 from being mixed together.

The tiled display device TD may have substantially a flat shape, but embodiments are not limited thereto. The tiled display device TD may have a stereoscopic shape and may thus provide the perception of depth (or a three-dimensional effect) to a user. For example, in a case where the tiled display device TD has a stereoscopic shape, at least some of the display devices 10 may have a curved shape. In another example, the display devices 10 may have a flat shape and may be connected to one another at a specific angle so that the tiled display device TD may have a stereoscopic shape.

The tiled display device TD may include a bonding area SM, which is disposed between display areas DA. The tiled display device TD may be implemented by connecting the non-display areas NDA of the display devices 10. The display devices 10 may be connected to one another via a bonding part or an adhesive part disposed in the bonding area SM. The bonding area SM may not include pad units or flexible films attached to pad units. Thus, the distance between the display areas DA of the display devices 10 may be so close that the bonding area SM may become almost invisible to the user. The reflectance of the display areas DA of the display devices 10 and the reflectance of the bonding area SM may be substantially the same. Thus, the tiled display device TD may overcome the perception of discontinuity between the display devices 10 and improve the degree of immersion of an image by preventing the bonding area SM from being recognized to the user.

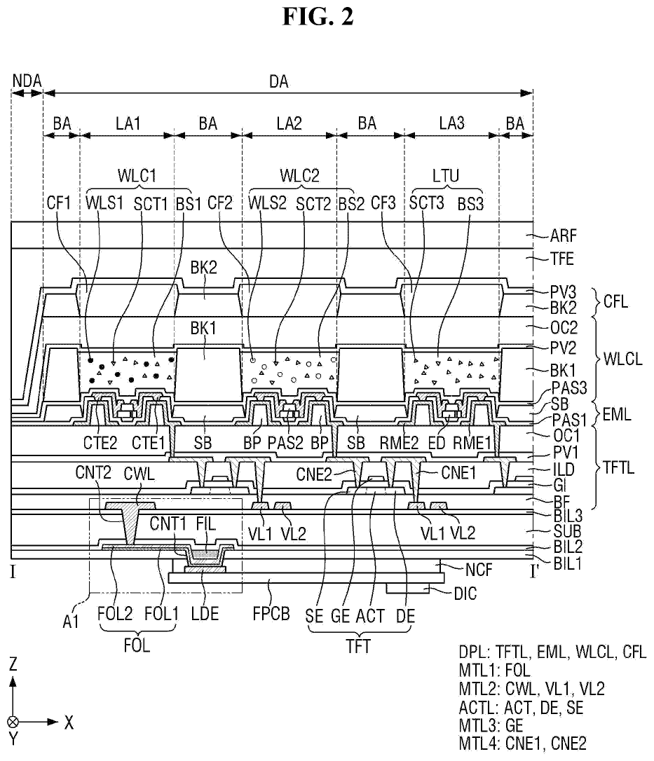

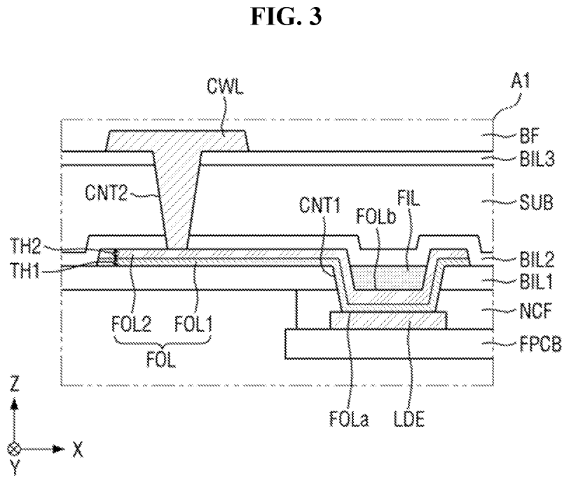

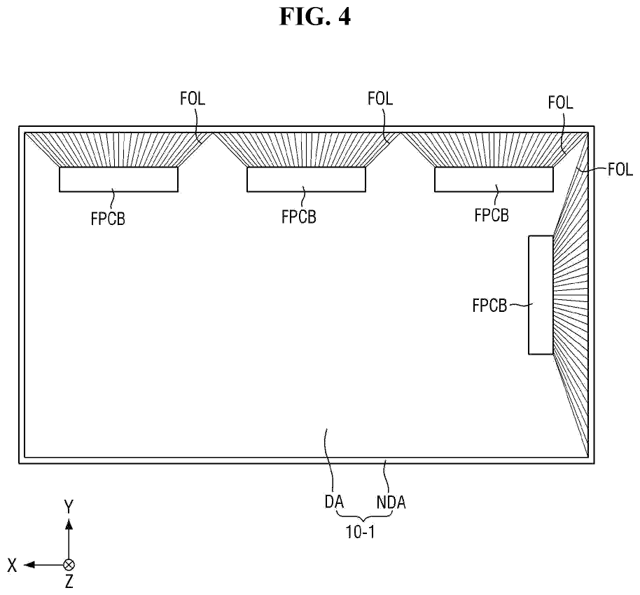

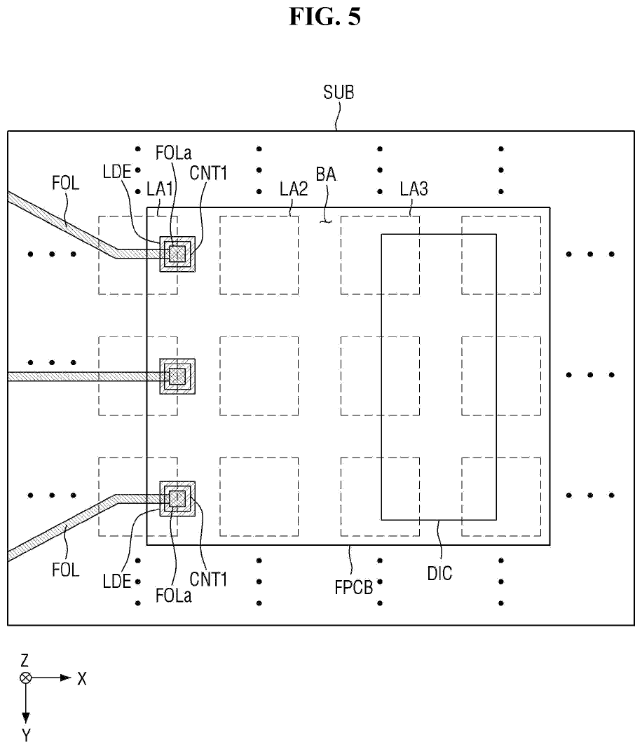

FIG. 2 is a schematic cross-sectional view taken along line I-I′ of FIG. 1. FIG. 3 is a schematic enlarged cross-sectional view of an area A1 of FIG. 2. FIG. 4 is a schematic bottom view of a display device according to an embodiment. FIG. 5 is a schematic enlarged bottom view of the display device of FIG. 4.

Referring to FIGS. 2, 3, 4, and 5, a display area DA of a display device 10 may include first emission areas LA1, second emission areas LA2, and third emission areas LA3. The first emission areas LA1, the second emission areas LA2, and the third emission areas LA3 may be areas that output light generated by light-emitting elements ED of the display device 10 to the outside of the display device 10.

The display device 10 may include a first barrier insulating layer BILL a first metal layer MTL1, filler parts FIL, a second barrier insulating layer BIL2, a substrate SUB, a third barrier insulating layer BIL3, a display layer DPL, an encapsulation layer TFE, an antireflection film ARF, flexible films FPCB, and display drivers DIC.

The first barrier insulating layer BIL1 may be disposed at the bottom portion of the display device 10. The first barrier insulating layer BIL1 may include an inorganic film capable of preventing the infiltration (or permeation) of the air or moisture. For example, the first barrier insulating layer BIL1 may include at least one of a silicon nitride layer, a silicon oxynitride layer, a silicon oxide layer, a titanium oxide layer, an aluminum oxide layer, and an amorphous silicon layer, but embodiments are not limited thereto.

The first barrier insulating layer BIL1 may include first contact holes CNT1. The first contact holes CNT1 may be etched from the top surface of the first barrier insulating layer BIL1 to penetrate through to the bottom surface of the first barrier insulating layer BIL1. For example, the upper width of the first contact holes CNT1 may be greater than the lower width of the first contact holes CNT1.

The first metal layer MTL1 may be disposed on the first barrier insulating layer BIL1. The first metal layer MTL1 may include fan-out lines FOL. The first metal layer MTL1 may be formed as a single layer or a multilayer including at least one of molybdenum (Mo), aluminum (Al), chromium (Cr), gold (Au), silver (Ag), titanium (Ti), nickel (Ni), palladium (Pd), indium (In), neodymium (Nd), and copper (Cu).

The fan-out lines FOL may include lower fan-out lines FOL1, which are disposed on the first barrier insulating layer BILL and upper fan-out lines FOL2, which are disposed on the lower fan-out lines FOL1. For example, the lower fan-out lines FOL1 may include titanium (Ti) and may thus be able to be readily formed on the first barrier insulating layer BIL1. However, the material of the lower fan-out lines FOL1 is not limited thereto. The upper fan-out lines FOL2 may include copper (Cu) and may thus be readily in contact with connecting lines CWL, which are inserted in second contact holes CNT2. However, the material of the upper fan-out lines FOL2 is not limited thereto. The thickness TH2 of the upper fan-out lines FOL2 may be about ten times or greater the thickness TH1 of the lower fan-out lines FOL1, but embodiments are not limited thereto.

Referring to FIG. 3, the fan-out lines FOL may connect (e.g., electrically connect) the flexible films FPCB and the connecting lines CWL. Protruding parts FOLa of the fan-out lines FOL may be inserted in the first contact holes CNT1 and may protrude beyond the bottom surface of the first barrier insulating layer BIL1. The protruding parts FOLa of the fan-out lines FOL may be in contact with (e.g., in direct contact with) lead electrodes LDE of the flexible films FPCB. The fan-out lines FOL may be connected (e.g., electrically connected) to data lines, power lines, or gate lines through the connecting lines CWL. The data lines or the power lines may be connected to drain electrodes DE of thin-film transistors (TFTs) “TFT”. The gate lines may be connected to gate electrodes GE of the TFTs “TFT”. Thus, the fan-out lines FOL may provide data voltages, power supply voltages, or gate signals from the display drivers DIC of the flexible films FPCB to the TFTs “TFT”. As the display device 10 includes the fan-out lines FOL in the display area DA, the size of the non-display area NDA may be minimized or reduced.

The filler parts FIL may be disposed in recessed parts FOLb of the fan-out lines FOL. The filler parts FIL may fill the recessed parts FOLb of the fan-out lines FOL, which are formed by the first contact holes CNT1. The top surfaces of the filler parts FIL may be lower than the top surfaces of the fan-out lines FOL, but embodiments are not limited thereto. The filler parts FIL may prevent the substrate SUB from being depressed or deformed, and as a result, the substrate SUB may have a flat top surface.

For example, the filler parts FIL may include an organic material. The filler parts FIL may include at least one of an acrylic resin, an epoxy resin, a phenolic resin, a polyamide resin, and a polyimide resin.

In another example, the filler parts FIL may include photoresist. The filler parts FIL may include positive photoresist or negative photoresist.

The second barrier insulating layer BIL2 may be disposed on the first barrier insulating layer BILL the first metal layer MTL1, and the filler parts FIL. The second barrier insulating layer BIL2 may include an inorganic film capable of preventing the infiltration of the air or moisture. For example, the second barrier insulating layer BIL2 may include at least one of a silicon nitride layer, a silicon oxynitride layer, a silicon oxide layer, a titanium oxide layer, an aluminum oxide layer, and an amorphous silicon layer, but embodiments are not limited thereto.

The substrate SUB may be disposed on the second barrier insulating layer BIL2. The substrate SUB may support the display device 10. The substrate SUB may be a base substrate or a base member. The substrate SUB may be a flexible substrate that is bendable, foldable, or rollable. For example, the substrate SUB may include an insulating material such as a polymer resin, for example, polyimide (PI), but embodiments are not limited thereto. In another example, the substrate SUB may be a rigid substrate including a glass material.

The third barrier insulating layer BIL3 may be disposed on the substrate SUB. The third barrier insulating layer BIL3 may include an inorganic film capable of preventing the infiltration of the air or moisture. For example, the second barrier insulating layer BIL2 may include at least one of a silicon nitride layer, a silicon oxynitride layer, a silicon oxide layer, a titanium oxide layer, an aluminum oxide layer, and an amorphous silicon layer, but embodiments are not limited thereto.

The third barrier insulating layer BIL3, the substrate SUB, and the second barrier insulating layer BIL2 may include second contact holes CNT2. The second contact holes CNT2 may be etched from the top surface of the third barrier insulating layer BIL3 to penetrate through to the bottom surface of the second barrier insulating layer BIL2. For example, the upper width (or the upper diameter) of the second contact holes CNT2 may be greater than the lower width (or the lower diameter) of the second contact holes CNT2. During the fabrication of the display device 10, the top surfaces of the upper fan-out lines FOL2 may be exposed by the second contact holes CNT2, and the upper fan-out lines FOL2 may be in contact with the connecting lines CWL, which are inserted in the second contact holes CNT2.

The display layer DPL may be disposed on the third barrier insulating layer BIL3. The display layer DPL may include a TFT layer TFTL, a light-emitting element layer EML, a wavelength conversion layer WLCL, and a color filter layer CFL. The TFT layer TFTL may include a second metal layer MTL2, a buffer layer BF, an active layer ACTL, a gate insulating layer GI, a third metal layer MTL3, an interlayer insulating layer ILD, a fourth metal layer MTL4, a first passivation layer PV1, and a first planarization layer OC1.

The second metal layer MTL2 may be disposed on the third barrier insulating layer BIL3. The second metal layer MTL2 may include the connecting lines CWL, first voltage lines VL1, and second voltage lines VL2. The connecting lines CWL, the first voltage lines VL1, and the second voltage lines VL2 may be formed in the same layer and of the same material, but embodiments are not limited thereto. For example, the second metal layer MTL2 may be formed as a single layer or a multilayer including at least one of Mo, Al, Cr, Au, Ag, Ti, Ni, Pd, In, Nd, and Cu.

The connecting lines CWL may be inserted in the second contact holes CNT2 and may thus be connected (e.g., electrically connected) to the fan-out lines FOL. For example, the connecting lines CWL may be connected (e.g., electrically connected) to the data lines and may provide data voltages to the TFTs “TFT”. The connecting lines CWL may be connected (e.g., electrically connected) to the power lines and may provide power supply voltages to the TFTs “TFT”. The connecting lines CWL may be connected (e.g., electrically connected) to the gate lines and may provide gate signals to the gate electrodes GE of the TFTs “TFT”. Thus, the connecting lines CWL may provide the data voltages, the power supply voltages, or the gate signals from the display drivers DIC to the TFTs “TFT” through the fan-out lines FOL.

The first voltage lines VL1 and the second voltage lines VL2 may extend in the second direction (or the Y-axis direction) in the display area DA. The first voltage lines VL1 and the second voltage lines VL2 may be connected (e.g., electrically connected) to the fan-out lines FOL. The first voltage lines VL1 and the second voltage lines VL2 may be connected (e.g., electrically connected) to the TFTs “TFT” or the light-emitting elements ED. For example, the first voltage lines VL1 and the second voltage lines VL2 may be the data lines, driving voltage lines, low-potential lines, or initialization voltage lines, but embodiments are not limited thereto.

The buffer layer BF may be disposed on the second metal layer MTL2 and the third barrier insulating layer BIL3. The buffer layer BF may include an inorganic material capable of preventing the infiltration of the air or moisture. For example, the buffer layer BF may include inorganic films that are alternately stacked.

The active layer ACTL may be disposed on the buffer layer BF. The active layer ACTL may include semiconductor areas ACT, the drain electrodes DE, and the source electrodes SE of the TFTs “TFT”. The semiconductor areas ACT may overlap the gate electrodes GE in a thickness direction (or a Z-axis direction) and may be insulated from the gate electrodes GE by the gate insulating layer GI. The drain electrodes DE and the source electrodes SE may be implemented by forming conductors using the material of the semiconductor areas ACT. The TFTs “TFT” may form pixel circuits of the pixels. For example, the TFTs “TFT” may be driving transistors or switching transistors of the pixel circuits.

The gate insulating layer GI may be disposed on the active layer ACTL and the buffer layer BF. The gate insulating layer GI may insulate the semiconductor areas ACT and the gate electrodes of the TFTs “TFT”. The gate insulating layer GI may include contact holes that are penetrated by first connecting electrodes CNE1 and second connecting electrodes CNE2.

The third metal layer MTL3 may be disposed on the gate insulating layer GI. The third metal layer MTL3 may include the gate electrodes GE of the TFTs “TFT”. The gate electrodes GE may overlap the semiconductor areas ACT with the gate insulating layer GI interposed therebetween. The gate electrodes GE may receive gate signals from the gate lines. For example, the third metal layer MTL3 may be formed as a single layer or a multilayer including at least one of Mo, Al, Cr, Au, Ag, Ti, Ni, Pd, In, Nd, and Cu.

The interlayer insulating layer ILD may be disposed on the third metal layer MTL3. The interlayer insulating layer ILD may insulate the third and fourth metal layers MTL3 and MTL4. The interlayer insulating layer ILD may include contact holes that are penetrated by the first connecting electrodes CNE1 and the second connecting electrodes CNE2.

The fourth metal layer MTL4 may be disposed on the interlayer insulating layer ILD. The fourth metal layer MTL4 may include the first connecting electrodes CNE1 and the second connecting electrodes CNE2. The first connecting electrodes CNE1 and the second connecting electrodes CNE2 may be formed on the same layer (e.g., the interlayer insulating layer ILD) and may be formed of the same material, but embodiments are not limited thereto. For example, the fourth metal layer MTL4 may be formed as a single layer or a multilayer including at least one of Mo, Al, Cr, Au, Ag, Ti, Ni, Pd, In, Nd, and Cu.

The first connecting electrodes CNE1 may connect (e.g., electrically connect) the first voltage lines VL1 and the drain electrodes DE of the TFTs “TFT”. First ends of the first connecting electrodes CNE1 may be in contact with the first voltage lines VL1 of the second metal layer MTL2, and second ends of the first connecting electrodes CNE1 may be in contact with the drain electrodes DE of the active layer ACTL.

The second connecting electrodes CNE2 may connect (e.g., electrically connect) the source electrodes SE of the TFTs “TFT” and first electrodes RME1. First ends of the second connecting electrodes CNE2 may be in contact with the source electrodes SE of the active layer ACTL, and the first electrodes RME1 of the light-emitting element layer EML may be in contact with second ends of the second connecting electrodes CNE2.

The first passivation layer PV1 may be disposed on the fourth metal layer MTL4 and the interlayer insulating layer ILD. The first passivation layer PV1 may protect the TFTs “TFT”. The first passivation layer PV1 may include contact holes that are penetrated by the first electrodes RME1.

The first planarization layer OC1 may be disposed on the first passivation layer PV1 and may planarize the tops of the TFTs “TFT”. For example, the first planarization layer OC1 may include contact holes that are penetrated by the first electrodes RME1. Here, the contact holes of the first planarization layer OC1 may be connected to the contact holes of the first passivation layer PV1. The first planarization layer OC1 may include an organic insulating material such as polyimide (PI).

The light-emitting element layer EML may be disposed on the TFT layer TFTL. The light-emitting element layer EML may include protruding pattern layers BP, the first electrodes RME1, second electrodes RME2, a first insulating layer PAS1, sub-banks SB, the light-emitting elements ED, a second insulating layer PAS2, the first contact electrodes CTE1, second contact electrodes CTE2, and a third insulating layer PAS3.

The protruding pattern layers BP may be disposed on the first planarization layer OC1. The protruding pattern layers BP may protrude from the top surface of the first planarization layer OC1. The protruding pattern layers BP may be disposed in emission areas LA or in opening areas of the pixels. The light-emitting elements ED may be disposed between the protruding pattern layers BP. Each of the protruding pattern layers BP may have inclined side surfaces, and light emitted by the light-emitting elements ED may be reflected by the first electrodes RME1 or the second electrodes RME2 on the protruding pattern layers BP. For example, the protruding pattern layers BP may include an organic insulating material such as polyimide (PI).

The first electrodes RME1 may be disposed on the first planarization layer OC1 and the protruding pattern layers BP. The first electrodes RME1 may be disposed on protruding pattern layers BP on first sides of the light-emitting elements ED. The first electrodes RME1 may be disposed on inclined side surfaces of the protruding pattern layers BP on the first sides of the light-emitting elements ED to reflect light emitted by the light-emitting elements ED. The first electrodes RME1 may be inserted in the contact holes of the first planarization layer OC1 and the first passivation layer PV1 and may thus be connected to the second connecting electrodes CNE2. The first electrodes RME1 may be connected (e.g., electrically connected) to first ends of the light-emitting elements ED through the first contact electrodes CTE1. For example, the first electrodes RME1 may receive a voltage that is proportional to the luminance of the light-emitting elements ED, from the TFTs “TFT”.

The second electrodes RME2 may be disposed on the first planarization layer OC1 and the protruding pattern layers BP. The second electrodes RME2 may be disposed on protruding pattern layers BP on second sides of the light-emitting elements ED. The second electrodes RME2 may be disposed on inclined side surfaces of the protruding pattern layers BP on the second sides of the light-emitting elements ED to reflect light emitted by the light-emitting elements ED. The second electrodes RME2 may be connected (e.g., electrically connected) to second ends of the light-emitting elements ED through the second contact electrodes CTE2. For example, the second electrodes RME2 may receive a low-potential voltage to be supplied to all the pixels from low-potential lines.

The first electrodes RME1 and the second electrodes RME2 may include a conductive material having high reflectance. For example, the first electrodes RME1 and the second electrodes RME2 may include at least one of Al, Ag, Cu, Ni, and lanthanum (La). In another example, the first electrodes RME1 and the second electrodes RME2 may include a material such as indium tin oxide (ITO), indium zinc oxide (IZO), or indium tin zinc oxide (ITZO). In yet another example, the first electrodes RME1 and the second electrodes RME2 may include either multilayers having transparent conductive material layers and metal layers with high reflectance or single layers including a transparent conductive material or a high-reflectance metal. The first electrodes RME1 and the second electrodes RME2 may have a stack structure such as ITO/Ag/ITO/, ITO/Ag/IZO, or ITO/Ag/ITZO/IZO.

The first insulating layer PAS1 may be disposed on the first planarization layer OC1, the first electrodes RME1, and the second electrodes RME2. The first insulating layer PAS1 may protect and insulate the first electrodes RME1 and the second electrodes RME2. The first insulating layer PAS1 may prevent the light-emitting elements ED from being placed in contact with (e.g., in direct contact with) the first electrodes RME1 and the second electrodes RME2 during the alignment of the light-emitting elements ED.

The sub-banks SB may be disposed in a light-blocking area BA, on the first insulating layer PAS1. The sub-banks SB may be disposed along the boundaries of each of the pixels to define and separate the pixels. The sub-banks SB may have a specific height and may include an organic insulating material such as polyimide (PI).

The light-emitting elements ED may be disposed on the first insulating layer PAS1. The light-emitting elements ED may be aligned in parallel between the first electrodes RME1 and the second electrodes RME2. The length of the light-emitting elements ED may be greater than the distance between the first electrodes RME1 and the second electrodes RME2. Each of the light-emitting elements ED may include semiconductor layers, and the first ends and the second ends of the light-emitting elements ED may be defined based on one of the semiconductor layers. The first ends of the light-emitting elements ED may be disposed on the first electrodes RME1, and the second ends of the light-emitting elements ED may be disposed on the second electrodes RME2. The first ends of the light-emitting elements ED may be connected (e.g., electrically connected) to the first electrodes RME1 through the first contact electrodes CTE1, and the second ends of the light-emitting elements ED may be connected (e.g., electrically connected) to the second electrodes RME2 through the second contact electrodes CTE2.

The light-emitting elements ED may have a size of several micrometers or nanometers and may be inorganic light-emitting diodes (LEDs) including an inorganic material. The light-emitting elements ED may be aligned between each pair of opposing first and second electrodes RME1 and RME2 in accordance with an electric field formed in a specific direction between the corresponding pair of opposing first and second electrodes RME1 and RME2.

For example, the light-emitting elements ED may include active layers that include the same material, and may thus emit light of the same wavelength range or light of the same color. Beams of light emitted from the first emission areas LA1, the second emission areas LA2, and the third emission areas LA3 of the light-emitting element layer EML may all have the same color. For example, the light-emitting elements ED may emit third-color light or blue light having a peak wavelength of about 440 nm to about 480 nm, but embodiments are not limited thereto.

The second insulating layer PAS2 may be disposed on the light-emitting elements ED. For example, the second insulating layer PAS2 may surround parts of the light-emitting elements ED and may not cover ends (e.g., opposite ends) of each of the light-emitting elements ED. The second insulating layer PAS2 may protect the light-emitting elements ED and may fix the light-emitting elements ED during the fabrication of the display device 10. The second insulating layer PAS2 may fill the space between the light-emitting elements ED and the first insulating layer PAS1.

The first contact electrodes CTE1 may be disposed on the first insulating layer PAS1. The first contact electrodes CTE1 may be inserted in contact holes in the first insulating layer PAS1 and may thus be connected to the first electrodes RME1. For example, the contact holes in the first insulating layer PAS1 may be formed above the protruding pattern layers BP, but embodiments are not limited thereto. First ends of the first contact electrodes CTE1 may be connected to the first electrodes RME1, on the protruding pattern layers BP, and second ends of the first contact electrodes CTE1 may be connected to the first ends of the light-emitting elements ED.

The second contact electrodes CTE2 may be disposed on the first insulating layer PAS1. The second contact electrodes CTE2 may be inserted in contact holes in the first insulating layer PAS1 and may thus be connected to the second electrodes RME2. For example, the contact holes in the first insulating layer PAS1 may be formed above the protruding pattern layers BP, but embodiments are not limited thereto. First ends of the second contact electrodes CTE2 may be connected to the second ends of the light-emitting elements ED and second ends of the second contact electrodes CTE2 may be connected to the second electrodes RME2, on the protruding pattern layers BP.

The third insulating layer PAS3 may be disposed on the first contact electrodes CTE1, the second contact electrodes CTE2, the sub-banks SB, the first insulating layer PAS1, and the second insulating layer PAS2. The third insulating layer PAS3 may be disposed at the top portion of the light-emitting element layer EML to protect the light-emitting element layer EML. For example, the third insulating layer PAS3 may form the top surface of the light-emitting element layer EML.

The wavelength conversion layer WLCL may be disposed on the light-emitting element layer EML. The wavelength conversion layer WLCL may include first light-blocking members BK1, first wavelength converters WLC1, second wavelength converters WLC2, light transmitters LTU, a second passivation layer PV2, and a second planarization layer OC2.

The first light-blocking members BK1 may be disposed in the light-blocking area BA, on the third insulating layer PAS3. The first light-blocking members BK1 may overlap the sub-banks SB in the thickness direction (or the Z-axis direction). The first light-blocking members BK1 may block (or prevent) the transmission of light. The first light-blocking members BK1 may improve the color reproducibility of the display device 10 by preventing light emitted from the first emission areas LA1, light emitted from the second emission areas LA2, and light emitted from the third emission areas LA3 from being mixed together. In a plan view, the first light-blocking members BK1 may be arranged in a lattice pattern to surround the first emission areas LA1, the second emission areas LA2, and the third emission areas LA3.

The first wavelength converters WLC1 may be disposed in the first emission areas LA1, on the third insulating layer PAS3. The first wavelength converters WLC1 may be surrounded by the first light-blocking members BK1. The first wavelength converters WLC1 may convert (or shift) the peak wavelength of incident light into a first peak wavelength. Each of the first wavelength converters WLC1 may include a first base resin BS1, a first scatterer SCT1, and a first wavelength shifter WLS1.

The first base resin BS1 may include a material with relatively high light transmittance. The first base resin BS1 may be formed of a transparent organic material. For example, the first base resin BS1 may include at least one of the following organic materials: an epoxy resin, an acrylic resin, a cardo resin, and an imide resin.

The first scatterer SCT1 may have a different refractive index from the first base resin BS1 and may form an optical interface with the first base resin BS1. For example, the first scatterer SCT1 may include a light-scattering material or light-scattering particles capable of scattering at least some of light passing through (or transmitting) the first wavelength converters WLC1. For example, the first scatterer SCT1 may include a metal oxide such as titanium oxide (TiO₂), zirconium oxide (ZrO₂), aluminum oxide (Al₂O₃), indium oxide (In₂O₃), zinc oxide (ZnO), or tin oxide (SnO₂) or organic particles such as particles of an acrylic resin or a urethane resin. The first scatterer SCT1 may scatter light in random directions, regardless of the incidence direction of incident light thereupon, without substantially changing the peak wavelength of the incident light.

The first wavelength shifter WLS1 may convert (or shift) the peak wavelength of incident light into a first peak wavelength. For example, the first wavelength shifter WLS1 may convert blue light emitted by the light-emitting element layer EML into red light having a single peak wavelength of about 610 nm to about 650 nm and may emit the red light. The first wavelength shifter WLS1 may include quantum dots, quantum rods, or a phosphor. The quantum dots may be a specific material that emits light of a specific color in response to the transition of the electrons from a conduction band to a valence band.

Some of blue light emitted by the light-emitting element layer EML may not be converted into red light by the first wavelength shifters WLS1 of the first wavelength converters WLC1, but may pass through the first wavelength converters WLC1. Blue light incident upon first color filters CF1 without being converted into red light by the first wavelength shifters WLS1 may be blocked (or absorbed) by the first color filters CF1. Red light converted from blue light by the first wavelength converters WLC1 may pass through the first color filters CF1 and may be emitted to the outside of the display device 10. Accordingly, the first emission areas LA1 may emit red light.

The second wavelength converters WLC2 may be disposed in the second emission areas LA2, on the third insulating layer PASS. The second wavelength converters WLC2 may be surrounded by the first light-blocking members BK1. The second wavelength converters WLC2 may convert (or shift) the peak wavelength of incident light into a second peak wavelength. Each of the second wavelength converters WLC2 may include a second base resin BS2, a second scatterer SCT2, and a second wavelength shifter WLS2.

The second base resin BS2 may include a material with relatively high light transmittance. The second base resin BS2 may be formed of a transparent organic material. For example, the second base resin BS2 and the first base resin BS1 may include the same material.

The second scatterer SCT2 may have a refractive index different from that of the second base resin BS2 and may form an optical interface with the second base resin BS2. For example, the second scatterer SCT2 may include a light-scattering material or light-scattering particles capable of scattering at least some of light passing through (or transmitting) the second wavelength converters WLC2. For example, the second scatterer SCT2 may include the same material as the first scatterers SCT1 of the first wavelength converters WLC1.

The second wavelength shifter WLS2 may convert (or shift) the peak wavelength of incident light into a second peak wavelength, which is different from the first peak wavelength. For example, the second wavelength shifter WLS2 may convert blue light emitted by the light-emitting element layer EML into green light having a single peak wavelength of about 510 nm to about 550 nm and may emit the red light. The second wavelength shifter WLS2 may include quantum dots, quantum rods, or a phosphor. The second wavelength shifter WLS2 and the first wavelength shifters WLS1 of the first wavelength converters WLC1 may include the same material. The second wavelength shifter WLS2 may be formed as quantum dots, quantum rods, or a phosphor having a wavelength conversion range different from that of the first wavelength shifters WLS1 of the first wavelength converters WLC1.

The light transmitters LTU may be disposed in the third emission areas LA3, on the third insulating layer PAS3. The light transmitters LTU may be surrounded by the first light-blocking members BK1. The light transmitters LTU may transmit incident light therethrough with maintaining the peak wavelength of the incident light. Each of the light transmitters LTU may include a third base resin BS3 and a third scatterer SCT3.

The third base resin BS3 may include a material with relatively high light transmittance. The third base resin BS3 may be formed of a transparent organic material. For example, the third base resin BS3 and the first or second base resin BS1 or BS2 may include the same material.

The third scatterer SCT3 may have a refractive index different from that of the third base resin BS3. For example, the third scatterer SCT3 and the third base resin BS3 may form an optical interface. For example, the third scatterer SCT3 may include a light-scattering material or light-scattering particles capable of scattering at least some of light passing through (or transmitting) the light transmitters LTU. For example, the third scatterer SCT3, the first scatterers SCT1 of the first wavelength converters WLC1, and the second scatterers SCT2 of the second wavelength converters WLC2 may include the same material.

As the wavelength conversion layers WLCL are disposed (e.g., disposed directly) on the third insulating layer PAS3 of the light-emitting element layer EML, the display device 10 may not need an additional substrate for the first wavelength converters WLC1, the second wavelength converters WLC2, and the light transmitters LTU. Thus, the first wavelength converters WLC1, the second wavelength converters WLC2, and the light transmitters LTU may be readily aligned in the first emission areas LA1, the second emission areas LA2, and the third emission areas LA3, respectively, and the thickness of the display device 10 may be reduced or minimized.

The second passivation layer PV2 may cover the first wavelength converters WLC1, the second wavelength converters WLC2, the light transmitters LTU, and the first light-blocking members BK1. For example, the second passivation layer PV2 may seal the first wavelength converters WLC1, the second wavelength converters WLC2, and the light transmitters LTU and may thereby prevent the first wavelength converters WLC1, the second wavelength converters WLC2, and the light transmitters LTU from being damaged or contaminated. For example, the second passivation layer PV2 may include an inorganic material.

The second planarization layer OC2 may be disposed on the second passivation layer PV2 to planarize the tops of the first wavelength converters WLC1, the second wavelength converters WLC2, and the light transmitters LTU. For example, the second planarization layer OC2 may include an organic insulating material such as polyimide (PI).

The color filter layer CFL may be disposed on the wavelength conversion layer WLCL. The color filter layer CFL may include second light-blocking members BK2, the first color filters CF1, second color filters CF2, third color filters CF3, and a third passivation layer PV3.

The second light-blocking members BK2 may be disposed in the light-blocking area BA, on the second planarization layer OC2 of the wavelength conversion layer WLCL. The second light-blocking members BK2 may overlap the first light-blocking members BK1 or the sub-banks SB in the thickness direction (or the Z-axis direction). The second light-blocking members BK2 may block (or prevent) the transmission of light. The second light-blocking members BK2 may improve the color reproducibility of the display device 10 by preventing light emitted from the first emission areas LA1, light emitted from the second emission areas LA2, and light emitted from the third emission areas LA3 from being mixed together. For example, in a plan view, the second light-blocking members BK2 may be arranged in a lattice pattern to surround the first emission areas LA1, the second emission areas LA2, and the third emission areas LA3.

The first color filters CF1 may be disposed in the first emission areas LA1, on the second planarization layer OC2. The first color filters CF1 may be surrounded by the second light-blocking members BK2. The first color filters CF1 may overlap the first wavelength converters WLC1 in the thickness direction (or the Z-axis direction). The first color filters CF1 may selectively transmit first-color light (e.g., red light) therethrough and may block (or absorb) second-color light (e.g., green light) and third-color light (e.g., blue light). For example, the first color filters CF1 may be red filters and may include a red colorant.

The second color filters CF2 may be disposed in the second emission areas LA2, on the second planarization layer OC2. The second color filters CF2 may be surrounded by the second light-blocking members BK2. The second color filters CF2 may overlap the second wavelength converters WLC2 in the thickness direction (or the Z-axis direction). The second color filters CF2 may selectively transmit second-color light (e.g., green light) therethrough and may block (or absorb) first-color light (e.g., red light) and third-color light (e.g., blue light). For example, the second color filters CF2 may be green filters and may include a green colorant.

The third color filters CF3 may be disposed in the third emission areas LA3, on the second planarization layer OC2. The third color filters CF3 may be surrounded by the second light-blocking members BK2. The third color filters CF3 may overlap the light transmitters LTU in the thickness direction (or the Z-axis direction). The third color filters CF3 may selectively transmit third-color light (e.g., blue light) therethrough and may block (or absorb) first-color light (e.g., red light) and second-color light (e.g., green light). For example, the third color filters CF3 may be blue filters and may include a blue colorant.

The first color filters CF1, the second color filters CF2, and the third color filters CF3 may reduce the reflection of external light by absorbing some of the external light. Thus, the first color filters CF1, the second color filters CF2, and the third color filters CF3 may prevent color distortions that may be caused by the reflection of external light.

As the first color filters CF1, the second color filters CF2, and the third color filters CF3 are disposed (e.g., disposed directly) on the second planarization layer OC2 of the wavelength conversion layer WLCL, the display device 10 may not need an additional substrate for the first color filters CF1, the second color filters CF2, and the third color filters CF3. Thus, the thickness of the display device 10 may be reduced or minimized.

The third passivation layer PV3 may cover the first color filters CF1, the second color filters CF2, and the third color filters CF3. The third passivation layer PV3 may protect the first color filters CF1, the second color filters CF2, and the third color filters CF3.

The encapsulation layer TFE may be disposed on the third passivation layer PV3 of the color filter layer CFL. The encapsulation layer TFE may cover the top surface and side surface of the display layer DPL. For example, the encapsulation layer TFE may include at least one inorganic film and may prevent the infiltration (or permeation) of oxygen or moisture. The encapsulation layer TFE may also include at least one organic film and may protect the display device such as foreign materials such as dust.

The antireflection film ARF may be disposed on the encapsulation layer TFE. The antireflection film ARF may prevent the reflection of external light and may thus reduce the degradation of the visibility of the display device 10 that may be caused by the reflection of external light. The antireflection film ARF may protect the top surface of the display device 10. In another example, the antireflection film ARF may be omitted. For example, the antireflection film ARF may be replaced with a polarizing film.

Referring to FIGS. 4 and 5, the flexible films FPCB may be disposed below the first barrier insulating layer BIL1. The flexible films FPCB may be disposed along the edges of the bottom surface of the display device 10. The flexible films FPCB may be attached to the bottom surface of the first barrier insulating layer BIL1 via adhesive parts NCF. Referring to FIG. 5, the flexible films FPCB may include the lead electrodes LDE, which are disposed on the top surfaces of the flexible films FPCB. The lead electrodes LDE may be in contact with (e.g., in direct contact with) the protruding parts FOLa of the fan-out lines FOL. The flexible films FPCB may support the display drivers DIC, which are disposed on the bottom surfaces of the flexible films FPCB. The lead electrodes LDE may be connected (e.g., electrically connected) to the display drivers DIC via lead lines, which are disposed on the bottom surfaces of the flexible films FPCB. The flexible films FPCB may be connected to source circuit boards, below the first barrier insulating layer BIL1. The flexible films FPCB may transmit signals and voltages from the display drivers DIC to the display device 10.

The adhesive parts NCF may attach (or bond) the flexible films FPCB to the bottom surface of the first barrier insulating layer BIL1. The adhesive parts NCF may include an insulating adhesive material. As the lead electrodes LDE are in contact with (e.g., in direct contact with) the protruding parts FOLa of the fan-out lines FOL, the adhesive parts NCF may not include conductive balls of an anisotropic conductive film, and the manufacturing cost of the display device 10 may be reduced or minimized. The adhesive parts NCF may not overlap the protruding parts FOLa of the fan-out lines FOL in the thickness direction (or the Z-axis direction). The adhesive parts NCF may have a lower viscosity and a higher fluidity than an anisotropic conductive film. Thus, the adhesive parts NCF may readily move during the bonding of the flexible films FPCB and the first barrier insulating layer BIL1 and may reduce (or lower) the temperature and pressure for bonding the flexible films FPCB.

In another example, the adhesive parts NCF may include conductive balls or solder balls. The adhesive parts NCF may be attached via an anisotropic conductive film process, a jet soldering process, a solder paste process, or a solder film process, but embodiments are not limited thereto. For example, the lead electrodes LDE of the flexible films FPCB may be connected (e.g., electrically connected) to the protruding parts FOLa of the fan-out lines FOL through the conductive balls or the solder balls.

The display drivers DIC may be mounted on the flexible films FPCB. The display drivers DIC may be integrated circuits (ICs). The display drivers DIC may convert digital video data into analog data voltages in accordance with data control signals received from a timing controller and may provide the analog data voltages to the data lines in the display area DA through the flexible films FPCB. The display drivers DIC may provide power supply voltages from a power supply unit to the power lines of the display area DA through the flexible films FPCB. The display drivers DIC may generate gate signals in accordance with gate control signals and may sequentially provide the gate signals to gate lines in a specific order. As the display device 10 includes the fan-out lines FOL, which are disposed below the substrate SUB, and the display drivers DIC, which are disposed below the first barrier insulating layer BILL the size of the non-display area NDA may be reduced or minimized.

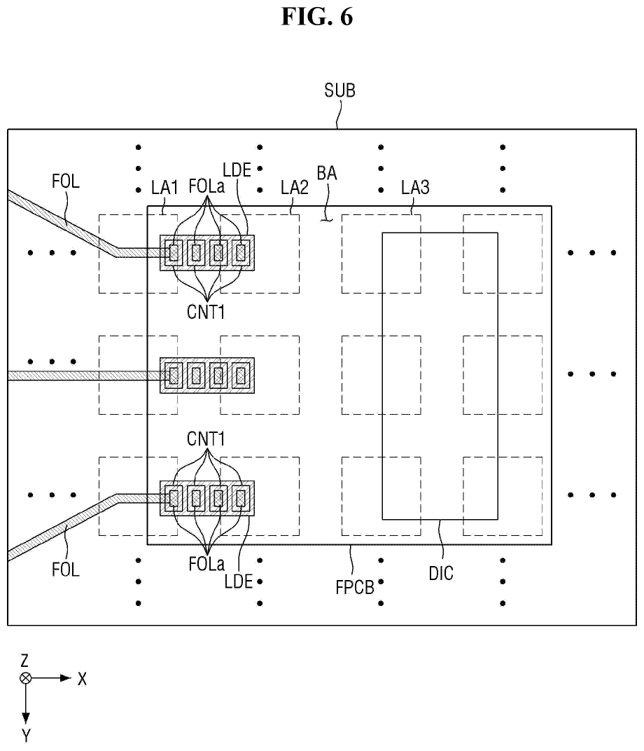

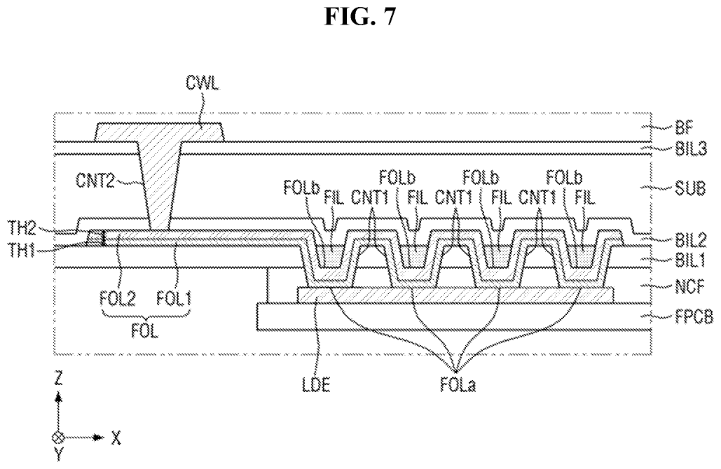

FIG. 6 is a schematic enlarged bottom view of a display device according to an embodiment. FIG. 7 is a schematic cross-sectional view of the display device of FIG. 6.

Referring to FIGS. 6 and 7, fan-out lines FOL may include lower fan-out lines FOL1, which are disposed on a first barrier insulating layer BILL and upper fan-out lines FOL2, which are disposed on the lower fan-out lines FOL1. For example, the lower fan-out lines FOL1 may include Ti and may thus be able to be readily formed on the first barrier insulating layer BIL1. However, the material of the lower fan-out lines FOL1 is not limited thereto. The upper fan-out lines FOL2 may include Cu and may thus be able to be readily in contact with connecting lines CWL, which are inserted in second contact holes CNT2. However, the material of the upper fan-out lines FOL2 is not limited thereto. The thickness TH2 of the upper fan-out lines FOL2 may be about ten times or greater the thickness TH1 of the lower fan-out lines FOL1, but embodiments are not limited thereto. The fan-out lines FOL may connect (e.g., electrically connect) flexible films FPCB and the connecting lines CWL.

Each of the fan-out lines FOL may include protruding parts FOLa. Each of the protruding parts FOLa may have short sides in a first direction (or an X-axis direction) and long sides in a second direction (or a Y-axis direction), and the protruding parts FOLa may be spaced apart from each other in the first direction (or the X-axis direction). The protruding parts FOLa may be inserted in first contact holes CNT1 and may protrude beyond the bottom surface of the first barrier insulating layer BIL1. The protruding parts FOLa may be in contact with (e.g., in direct contact with) one lead electrode LDE of a flexible film FPCB. The fan-out lines FOL may be connected (e.g., electrically connected) to data lines, power lines, or gate lines through the connecting lines CWL. The data lines or the power lines may be connected to drain electrodes DE of TFTs “TFT”. The gate lines may be connected to gate electrodes GE of the TFTs “TFT”. Thus, the fan-out lines FOL may provide data voltages, power supply voltages, or gate signals from a display driver DIC of the flexible film FPCB to the TFTs “TFT”. As the display device of FIGS. 6 and 7 includes the fan-out lines FOL in a display area DA, the size of a non-display area NDA may be reduced or minimized.

Filler parts FIL may be disposed in recessed parts FOLb of each of the fan-out lines FOL. The filler parts FIL may fill the recessed parts FOLb, which are formed by the first contact holes CNT1. The top surfaces of the filler parts FIL may be lower than the top surfaces of the fan-out lines FOL, but embodiments are not limited thereto. The filler parts FIL may prevent a substrate SUB from being depressed, and as a result, the substrate SUB may have a flat top surface.

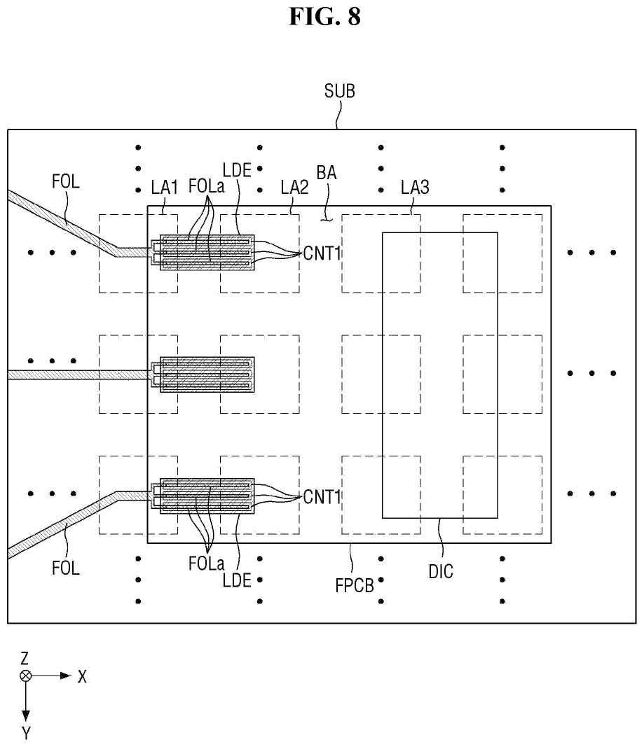

FIG. 8 is a schematic enlarged bottom view of a display device according to an embodiment.

Referring to FIG. 8, each of fan-out lines FOL may include protruding parts FOLa. The protruding parts FOLa may have long sides in a first direction (or an X-axis direction) and short sides in a second direction (or a Y-axis direction), and the protruding parts FOLa may be spaced apart from each other in the second direction (or the Y-axis direction). The protruding parts FOLa may be inserted in first contact holes CNT1 and may protrude beyond the bottom surface of a first barrier insulating layer BIL1. The protruding parts FOLa may be in contact with (e.g., in direct contact with) one lead electrode LDE of a flexible film FPCB. The fan-out lines FOL may be connected (e.g., electrically connected) to data lines, power lines, or gate lines through the connecting lines CWL. The data lines or the power lines may be connected to drain electrodes DE of TFTs “TFT”. The gate lines may be connected to gate electrodes GE of the TFTs “TFT”. Thus, the fan-out lines FOL may provide data voltages, power supply voltages, or gate signals from a display driver DIC of the flexible film FPCB to the TFTs “TFT”. As the display device of FIG. 8 includes the fan-out lines FOL in a display area DA, the size of a non-display area NDA may be reduced or minimized.

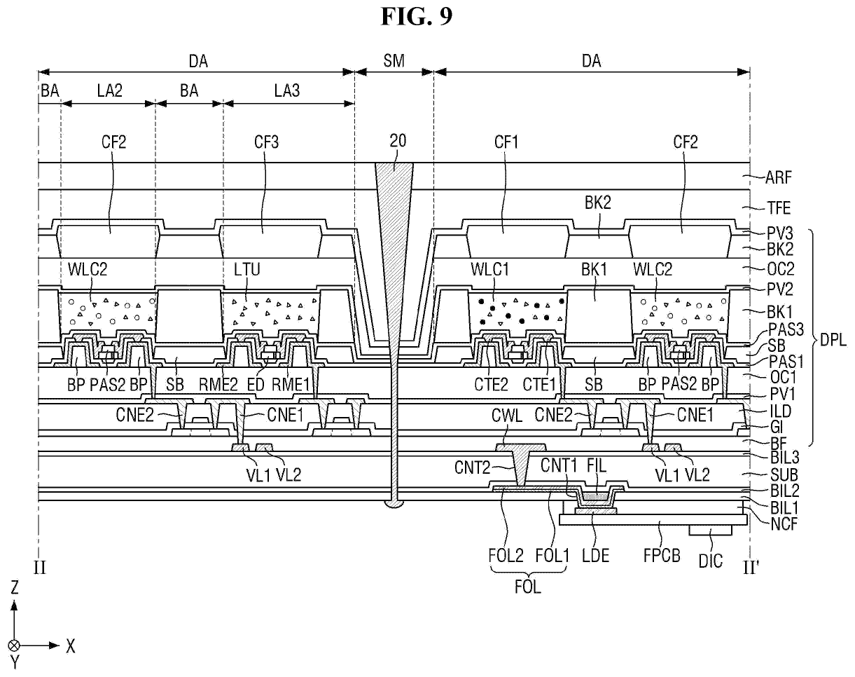

FIG. 9 is a schematic cross-sectional view taken along line II-IF of FIG. 1.

Referring to FIG. 9, the tiled display device TD may include display devices 10 and a bonding part 20. Specifically, the tiled display device TD may include the first, second, third, and fourth display devices 10-1, 10-2, 10-3, and 10-4. The number of display devices 10 included in the tiled display device TD and how the display devices 10 are coupled to one another are not limited thereto. The number of display devices 10 included in the tiled display device TD may be determined by the size of the display devices 10 and the size of the tiled display device TD.

Each of the display devices 10 may include a display area DA and a non-display area NDA. The display area DA may include pixels and may display an image. The non-display area NDA may be disposed around the display area DA to surround the display area DA and may not display an image.

Referring to FIG. 9, the tiled display device TD may include a bonding area SM, which is disposed between display areas DA. The tiled display device TD may be implemented by connecting the non-display areas NDA of the display devices 10. The display devices 10 may be connected to one another via a bonding part or an adhesive part disposed in the bonding area SM. The bonding area SM may not include pad units or fan-out lines attached to pad units. Thus, the distance between the display areas DA of the display devices 10 may be so close that the bonding area SM may be invisible to the user. The reflectance of the display areas DA of the display devices 10 may be substantially the same as the reflectance of the bonding area SM. Thus, the tiled display device TD may prevent the perception of discontinuity between the display devices 10 and improve the degree of immersion of an image by preventing the bonding area SM from being recognized to the user.

In the tiled display device TD, the sides of the display devices 10 may be bonded together via a bonding part 20, which is disposed between the display devices 10. The bonding part 20 may connect the sides of the first, second, third, and fourth display devices 10-1, 10-2, 10-3, and 10-4, which are arranged in a lattice pattern, and may thus implement the tiled display device TD. The bonding part 20 may couple the sides of first barrier insulating layers BIL1, second barrier insulating layers BIL2, substrates SUB, third barrier insulating layers BIL3, display layers DPL, encapsulation layers TFE, and antireflection films ARF of every two adjacent display devices 10 together.

For example, the bonding part 20 may be formed as a relatively thin adhesive or double-sided tape and may thus minimize the distance between the display devices 10. In another example, the bonding part 20 may be formed as a relatively thin bonding frame and may thus minimize the distance between the display devices 10. Thus, the tiled display device TD may prevent the bonding area SM between the display devices 10 from being recognized to the user.

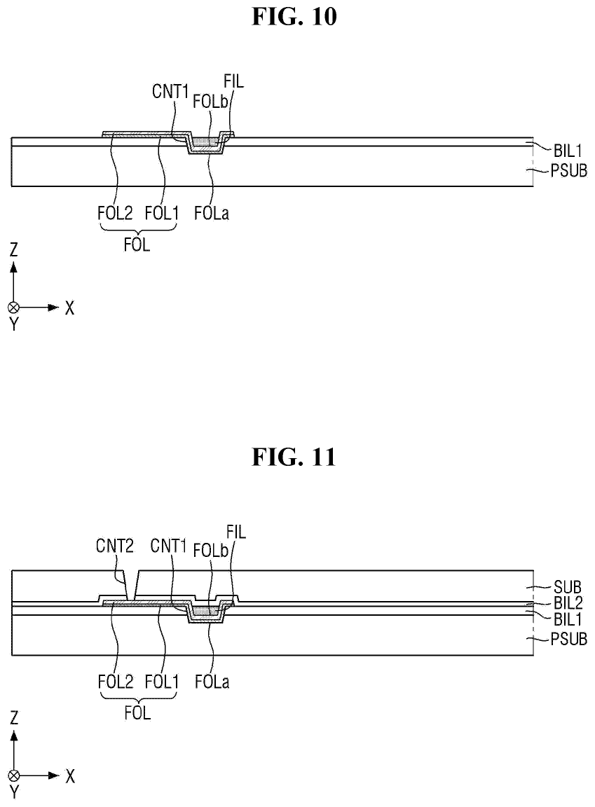

FIGS. 10, 11, 12, 13, 14, 15, and 16 are schematic cross-sectional views illustrating how to fabricate a display device according to an embodiment.

Referring to FIG. 10, a temporary substrate PSUB may support a display device 10 during the fabrication of the display device 10. For example, the temporary substrate PSUB may include an insulating material such as a polymer resin (e.g., polyimide), but embodiments are not limited thereto.

A first barrier insulating layer BIL1 may be disposed on the temporary substrate PSUB. The first barrier insulating layer BIL1 may include an inorganic film capable of preventing the infiltration (or permeation) of the air or moisture. Each of the first barrier insulating layer BIL1 and the temporary substrate PSUB may include a first contact hole CNT1. The first contact hole CNT1 may be etched from the top surface of the first barrier insulating layer BIL1 to penetrate through to the top surface of the temporary substrate PSUB. The first contact hole CNT1 may be formed by dry etching or wet etching, but embodiments are not limited thereto.

A fan-out line FOL may be disposed on the first barrier insulating layer BIL1 and may be inserted in the first contact hole CNT1. For example, the fan-out line FOL may be patterned on the first barrier insulating layer BIL1 by a photolithography process, a wet etching process, or a stripping process, but embodiments are not limited thereto.

The fan-out line FOL may include a lower fan-out line FOL1, which is disposed on the first barrier insulating layer BILL and an upper fan-out line FOL2, which is disposed on the lower fan-out line FOL1. For example, the lower fan-out line FOL1 may include Ti and may thus be able to be readily formed on the first barrier insulating layer BIL1. However, the material of the lower fan-out line FOL1 is not limited thereto. The upper fan-out line FOL2 may include Cu and may thus be able to be readily in contact with a connecting line CWL, which is inserted in a second contact hole CNT2. However, the material of the upper fan-out line FOL2 is not limited thereto. The thickness TH2 of the upper fan-out line FOL2 may be about ten times or greater the thickness TH1 of the lower fan-out line FOL1, but embodiments are not limited thereto.

A protruding part FOLa of the fan-out line FOL may be inserted in the first contact hole CNT1 and may protrude beyond the bottom surface of the first barrier insulating layer BIL1. A filler part FIL may be disposed in a recessed part FOLb of the fan-out line FOL. The filler part FIL may fill the recessed part FOLb of the fan-out line FOL, which is formed by the first contact hole CNT1.

Referring to FIG. 11, a second barrier insulating layer BIL2 may be disposed on the first barrier insulating layer BILL the fan-out line FOL, and the filler part FIL. A substrate SUB and the third barrier insulating layer BIL3 may be sequentially stacked on the second barrier insulating layer BIL2. A second contact hole CNT2 may be etched from the top surface of the third barrier insulating layer BIL3 to penetrate through to the bottom surface of the second barrier insulating layer BIL2. For example, the second and third barrier insulating layers BIL2 and BIL3 and the substrate SUB may be penetrated by a dry etching process or a wet etching process, but embodiments are not limited thereto. The top surface of the upper fan-out line FOL2 may be exposed by the second contact hole CNT2.

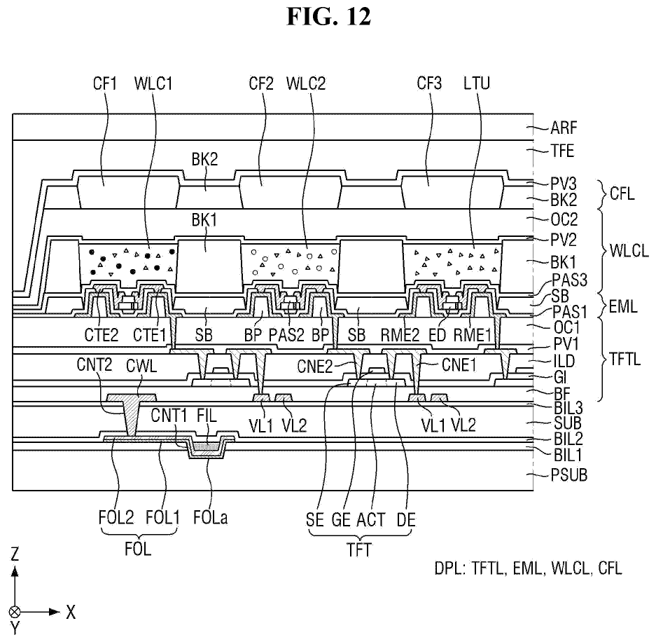

Referring to FIG. 12, a display layer DPL may be stacked on the third barrier insulating layer BIL3. A TFT layer TFTL, a light-emitting element layer EML, a wavelength conversion layer WLCL, and a color filter layer CFL may be sequentially stacked on the third barrier insulating layer BIL3. An encapsulation layer TFE may cover the top surface and sides of the display layer DPL. An antireflection film ARF may be formed on the encapsulation layer TFE.

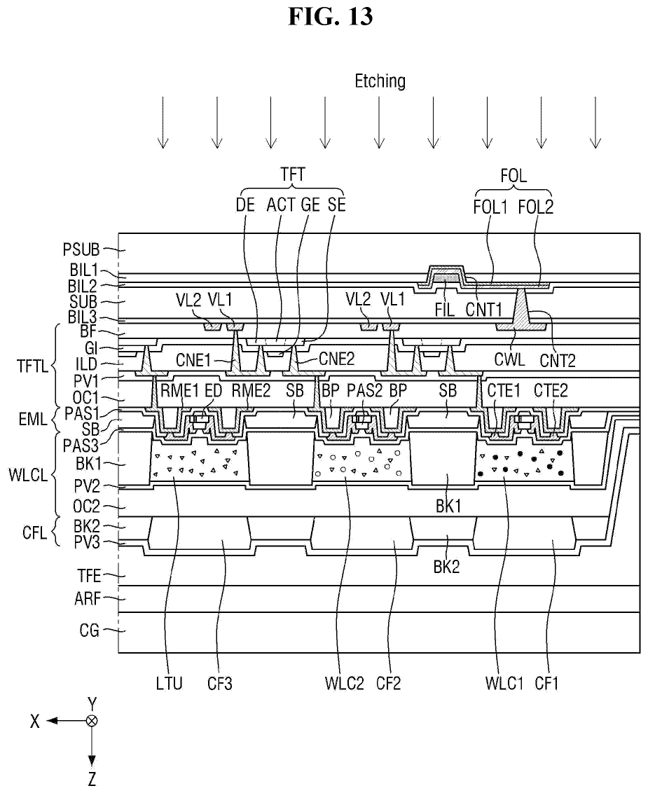

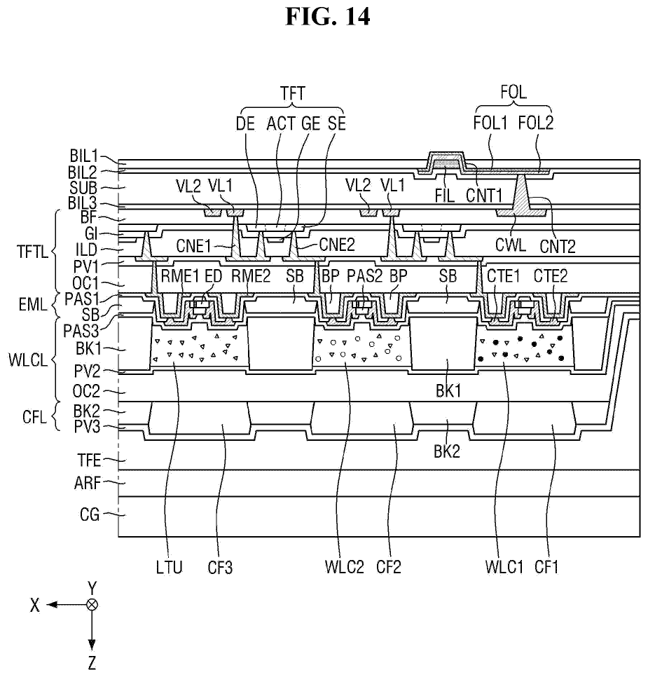

Referring to FIGS. 13 and 14, the display device 10 may be turned upside down to form a flexible film FPCB.

A carrier substrate CG may be disposed on one surface of the antireflection film ARF. The carrier substrate CG may support the display device 10 that has been turned upside down. For example, the carrier substrate CG may be carrier glass, but embodiments are not limited thereto.

The temporary substrate PSUB may be etched by an atmospheric pressure (AP) plasma process using an etching gas or a laser etching process. As the temporary substrate PSUB is removed, the protruding part FOLa of the fan-out line FOL may protrude beyond the first barrier insulating layer BIL1.

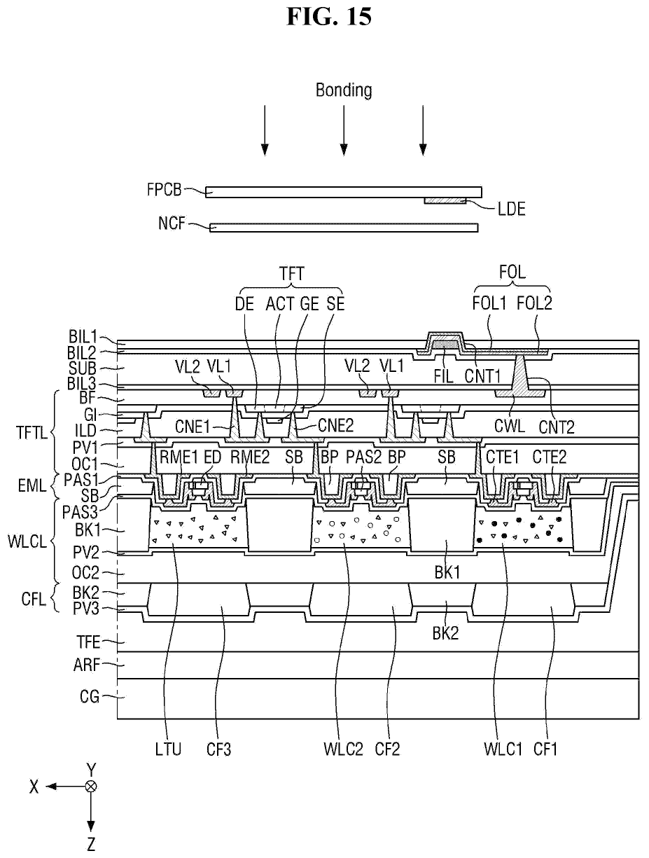

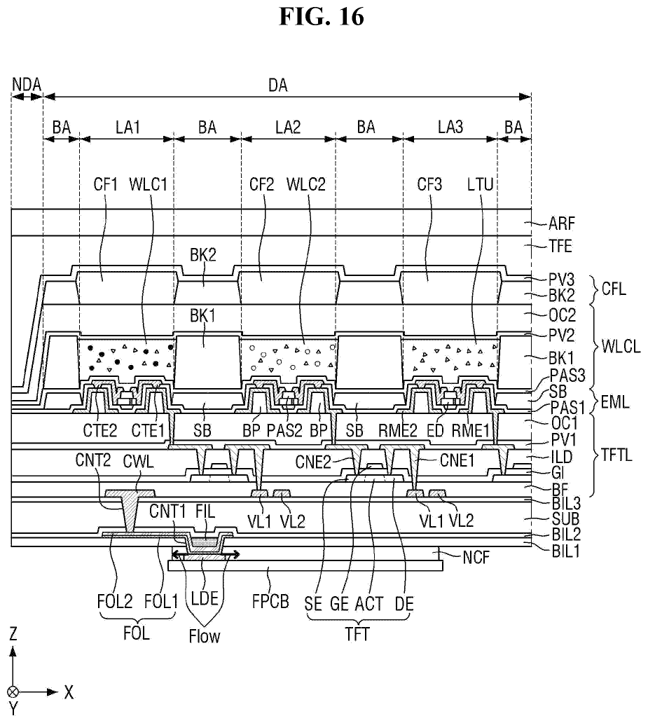

Referring to FIGS. 15 and 16, the flexible film FPCB may be disposed on one surface of the first barrier insulating layer BIL1. The flexible film FPCB and an adhesive part NCF may be aligned on the protruding part FOLa of the fan-out line FOL. For example, the flexible film FPCB and the adhesive part NCF may be attached to the surface of the first barrier insulating layer BIL1 through ultrasonic bonding, but embodiments are not limited thereto. A lead electrode LDE may be in contact with (e.g., in direct contact with) the protruding part FOLa of the fan-out line FOL.

The adhesive part NCF may attach the flexible film FPCB to the bottom surface of the first barrier insulating layer BIL1. The adhesive part NCF may include an insulating adhesive material. As the lead electrode LDE is in contact with (e.g., in direct contact with) the protruding part FOLa of the fan-out line FOL, the adhesive part NCF may not include conductive balls of an anisotropic conductive film, and the manufacturing cost of the display device 10 may be reduced or minimized. The adhesive part NCF may have a lower viscosity and a higher fluidity than an anisotropic conductive film. Thus, the adhesive part NCF may readily move during the bonding of the flexible film FPCB and the first barrier insulating layer BIL1 and may reduce the temperature and pressure for bonding the flexible film FPCB.

In another example, the adhesive part NCF may include conductive balls or solder balls. The adhesive parts NCF may be attached via an anisotropic conductive film process, a jet soldering process, a solder paste process, or a solder film process, but embodiments are not limited thereto. For example, the lead electrode LDE of the flexible film FPCB may be connected (e.g., electrically connected) to the protruding parts FOLa of the fan-out lines FOL through the conductive balls or the solder balls.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a first barrier insulating layer including a first contact hole;
a first metal layer disposed on the first barrier insulating layer, the first metal layer including:
a protruding part inserted in the first contact hole to protrude from below the first barrier insulating layer, and
a recessed part formed in the first contact hole;
a substrate disposed on the first metal layer and including a second contact hole;
a second metal layer disposed on the substrate and inserted in the second contact hole to be connected to the first metal layer;
a thin-film transistor including an active layer and a third metal layer overlapping the active layer; and
a flexible film disposed below the first barrier insulating layer and including a lead electrode electrically connected to the protruding part of the first metal layer.

2. The display device of claim 1, further comprising an adhesive part having an insulating property and attaching the flexible film to a bottom surface of the first barrier insulating layer.

3. The display device of claim 1, further comprising a filler part filling the recessed part of the first metal layer.

4. The display device of claim 3, wherein the filler part includes an organic material or photoresist.

5. The display device of claim 3, further comprising a second barrier insulating layer disposed on the first barrier insulating layer, the first metal layer, and the filler part.

6. The display device of claim 1, wherein
the first barrier insulating layer includes a plurality of first contact holes,
the first metal layer includes a plurality of protruding parts inserted in each of the plurality of first contact holes, and
the lead electrode is in direct contact with the plurality of protruding parts.

7. The display device of claim 6, wherein
each of the plurality of protruding parts has short sides in a first direction and long sides in a second direction intersecting the first direction, and
the plurality of protruding parts are spaced apart from each other in the first direction.

8. The display device of claim 1, wherein
the first metal layer includes a fan-out line,
the fan-out line includes:
a lower fan-out line disposed on the first barrier insulating layer, and
an upper fan-out line disposed on the lower fan-out line, and
a thickness of the upper fan-out line is greater than a thickness of the lower fan-out line.

9. The display device of claim 1, wherein the flexible film provides a data voltage, a power supply voltage, or a gate signal to the thin-film transistor through the first metal layer.

10. The display device of claim 9, further comprising a display driver mounted on the flexible film and providing the data voltage, the power supply voltage, or the gate signal.

11. The display device of claim 1, wherein
the second metal layer includes a connecting line and a voltage line, and
the voltage line is electrically connected to the thin-film transistor.

12. The display device of claim 11, further comprising a fourth metal layer disposed on the third metal layer, wherein
the fourth metal layer include a first connecting electrode,
an end of the first connecting electrode is connected to the voltage line, and
another end of the first connecting electrode is connected to the thin-film transistor.

13. The display device of claim 12, further comprising a light-emitting element layer disposed on the fourth metal layer, wherein
the fourth metal layer further includes a second connecting electrode, and
the light-emitting element layer comprises:
a first electrode connected to the second connecting electrode;
a second electrode spaced apart from the first electrode; and
light-emitting elements aligned between the first and second electrodes and electrically connected between the first and second electrodes.

14. A display device comprising:
a barrier insulating layer including a first contact hole;
a first metal layer disposed on the barrier insulating layer, the first metal layer including a protruding part inserted in the first contact hole to protrude from below the barrier insulating layer, and a recessed part formed in the first contact hole;
a substrate disposed on the first metal layer and including a second contact hole;
a second metal layer disposed on the substrate;
a thin-film transistor electrically connected to the second metal layer;
a flexible film disposed below the barrier insulating layer and including a lead electrode electrically connected to the protruding part of the first metal layer; and
an adhesive part not overlapping the protruding part of the first metal layer in a thickness direction.

15. The display device of claim 14, further comprising a filler part filling the recessed part of the first metal layer.

16. The display device of claim 15, wherein the adhesive part does not overlap the filler part in the thickness direction.

17. The display device of claim 14, wherein
the second metal layer includes a connecting line, and
the connecting line is inserted in the second contact hole to be connected to the first metal layer.

18. The display device of claim 14, wherein the thin-film transistor includes:
an active layer including a drain electrode, a semiconductor area, and a source electrode; and
a gate electrode disposed on the active layer.

19. The display device of claim 13, wherein
the first metal layer includes a fan-out line,
the second metal layer includes a voltage line, and
the voltage line is electrically connected to the thin-film transistor.

20. A tiled display device comprising:
a plurality of display devices, each of the display devices having a display area including a plurality of pixels, and a non-display area surrounding the display area; and
a bonding part bonding the display devices to one another, wherein
each of the display devices comprises:
a barrier insulating layer including a first contact hole;
a first metal layer disposed on the barrier insulating layer and including a protruding part inserted in the first contact hole to protrude from below the barrier insulating layer;
a substrate disposed on the first metal layer and including a second contact hole;
a second metal layer disposed on the substrate;
a thin-film transistor electrically connected to the second metal layer; and
a flexible film disposed below the barrier insulating layer and including a lead electrode electrically connected to the protruding part of the first metal layer.
